(19) United States
(12) Patent Application Publication
(10) Pub. No.: US 2023/0197905 A1
(43) Pub. Date: Jun. 22, 2023

(54) LIGHT-EMITTING DEVICE AND FORMING METHOD THEREOF

(71) Applicant: Lextar Electronics Corporation, Hsinchu City (TW)

(72) Inventors: Jih-Kang CHEN, Hsinchu City (TW); Shiou-Yi KUO, Hsinchu City (TW); Guo-Yi SHIU, Hsinchu City (TW)

(21) Appl. No.: 18/078,018

(22) Filed: Dec. 8, 2022

(30) Foreign Application Priority Data
Dec. 16, 2021 (TW) 110147112

(51) Int. Cl. H01L 33/46; H01L 25/075; H01L 33/38; H01L 33/00

(52) U.S. Cl. CPC H01L 33/46; H01L 25/0753; H01L 33/382; H01L 33/005; H01L 2933/0016; H01L 2933/0025

(57) ABSTRACT

A light-emitting device includes a substrate, a plurality of light-emitting diode (LED) dies, a first reflection layer, and a second reflection layer. The LED dies are on the substrate. The first reflection layer is on the LED dies. The second reflection layer is on the first reflection layer. The first reflection layer is configured to reflect a waveband of light emitted from the LED dies. The second reflection layer is configured to reflect a laser waveband, wherein the wavelength of the laser waveband is less than 420 nm.

### CROSS REFERENCE TO RELATED APPLICATIONS

This application claims priority of Taiwan Patent Application No. 110147112, filed on Dec. 16, 2021, the entirety of which is incorporated by reference herein.

### BACKGROUND

### Technical Field

The present disclosure relates to light-emitting devices, and in particular, to light-emitting devices with a reflection layer.

### Description of the Related Art

Light-emitting diodes (LEDs) are light-emitting devices that emit light when a voltage is applied. Nitride semiconductor LEDs are generally used as optoelectronic components to emit blue light or green light. Considering the lattice matching of the semiconductor compounds, a nitride semiconductor material is generally grown on a sapphire substrate, and then an electrode structure is formed to form a nitride LED. However, the sapphire substrate has high hardness, low thermal conductivity, and low electrical conductivity, which not only has problems with static electricity, but is also the main factor that limits the heat dissipation of the original LED chip. In addition, in the original LED structure, the electrodes block a part of the light and then reduce luminous efficiency. Therefore, flip chip structures for LEDs have gradually been developed.

Currently, the most common LED flip-chip technique is to flip and solder a prepared LED chip to the package substrate. Since the LED chip is reversed, the heat conduction path can be directly conducted from the semiconductor layer to the package substrate, thereby avoiding the problem of poor heat dissipation of the sapphire substrate. Besides, during a traditional process flow of forming the flip-chip, the LED chips formed in an array are transferred from one carrier to another carrier by using a pick-up head corresponding to each chip. However, there are some difficulties inherent in the traditional process. For example, when the side length of a micro-LED die is smaller than the minimum size of the pick-up head, it is impossible to pick up the LED chip effectively. In another example, the scaling down of the die size means that the number of dies that can be formed on the same-sized wafer is increased enormously. Therefore, the one-to-one pick-up method in the traditional process fails to meet the needs of transferring a large number of LED chips, resulting in a decrease in the yield of LEDs.

In the evolution of the technology for mass transferring LED chips, in order to meet high efficiency requirements and achieve higher production capacity, a selective laser lift-off (selective LLO) technique has been used to replace the traditional process.

### BRIEF SUMMARY

An embodiment of the present disclosure provides a light-emitting device, which includes a substrate, a plurality of light-emitting diode (LED) dies, a first reflection layer, and a second reflection layer. The LED dies are on the substrate. The first reflection layer is on the LED dies. The second reflection layer is on the first reflection layer. The first reflection layer is configured to reflect a waveband of light emitted from the LED dies. The second reflection layer is configured to reflect a laser waveband, wherein the wavelength of the laser waveband is less than 420 nm.

An embodiment of the present disclosure provides a light-emitting device, which includes a carrier, a plurality of LED dies, and a plurality of glues. The LED dies are on the substrate and spaced apart from each other, wherein each of the LED dies includes a pair of electrodes facing toward the carrier. The glues are between the carrier and the LED dies and wrapping the electrodes, wherein the upper surfaces of the carrier are exposed between the LED dies.

An embodiment of the present disclosure provides a light-emitting device, which includes a carrier, an LED die on the substrate, an adhesion layer, and a glue. The die is on the substrate, wherein the LED die includes a pair of electrodes facing away from the carrier. The adhesion layer is disposed between the carrier and the LED die. The glue is over the LED die, wherein the electrodes are exposed from the glue.

An embodiment of the present disclosure provides a method, which includes providing a substrate. The substrate has a plurality of LED dies spaced apart from each other, and the front side of each of the LED dies has a pair of electrodes facing away from the substrate. The method further includes bonding a first carrier to the front side of the LED dies through a glue, with the electrodes facing toward the first carrier. The method further includes removing the substrate from a back side of the LED dies. The method further includes removing a part of the glue between the LED dies to expose upper surfaces of the first carrier between the LED dies. The method further includes bonding a second carrier to the back side of the LED dies through an adhesion layer. The method further includes removing the first carrier from the front side of at least one of the LED dies, such that the at least one of the LED dies adheres to the second carrier. The method further includes removing a part of the glue on the at least one of the LED dies on the second carrier to expose the electrodes. The method further includes bonding a back plate to the exposed electrodes on the at least one of the LED dies. The method further includes removing the second carrier and the adhesion layer from the back side of the at least one of the LED dies.

### BRIEF DESCRIPTION OF THE DRAWINGS

Aspects of the present disclosure can be more fully understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 illustrates a cross-sectional view of a light-emitting device in accordance with some embodiments of the present disclosure.

FIG. 2 illustrates a cross-sectional view of an LED die in accordance with some embodiments of the present disclosure.

FIGS. 3A-3D illustrate cross-sectional views of various intermediate stages of fabrication of an LED die in accordance with some embodiments of the present disclosure.

FIGS. 4A-4D illustrate cross-sectional views of an LED die has different type and/or different profile of reflection layer in accordance with embodiments of the present disclosure.

FIG. 5 illustrates a cross-sectional view of an LED die has a light-emitting layer in accordance with some embodiments of the present disclosure.

FIG. 6 illustrates a cross-sectional view of an LED die has a barrier layer in accordance with some embodiments of the present disclosure.

FIGS. 7-19 illustrate cross-sectional views of various intermediate stages of mass transfer process of LED dies in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, in some embodiments of the present disclosure, terms related to joining and connecting, such as “connected”, “interconnected”, unless otherwise specified, may mean that two structures are in direct contact, or may also mean that two structures are not in direct contact and there are other structures located between the two structures. Moreover, the terms of joining and connecting are intended to encompass the case where both structures are movable or both structures are fixed.

Further, spatially relative terms, such as “beneath,” “below,” “lower,” “above,” “upper” and the like, may be used herein for ease of description to describe relationships between elements or features as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

Some embodiments of the present disclosure provide a light-emitting device with a first reflection layer on an LED die and a second reflection layer on the first reflection layer. Currently, in the process of mass transfer of the LED dies, while using the selective LLO technique, the high temperature caused by the laser may damage the LED dies, thus reducing the yield of LED dies and affecting the performance of the light-emitting devices. In order to solve the above problems, some embodiments of the present disclosure provide a light-emitting device with two reflection layers disposed on an LED die. Therefore, the external quantum efficiency (EQE) of the LED die can be improved, and the LED die can also reflect the laser used in the selective LLO technique to prevent the LED die from being damaged.

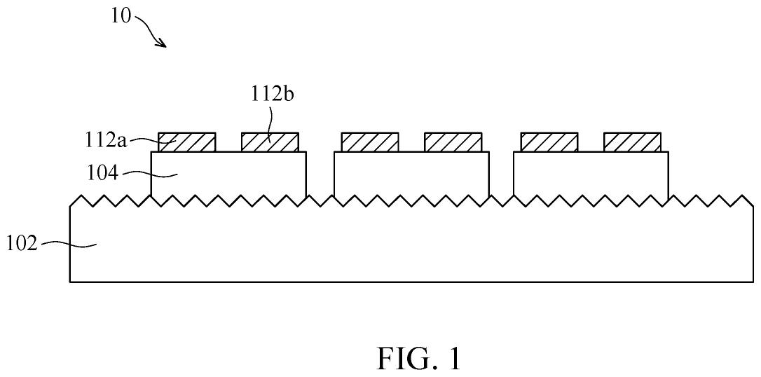

FIG. 1 illustrates a cross-sectional view of a light-emitting device 10 in accordance with an embodiment of the present disclosure. In FIG. 1, the light-emitting device 10 includes a substrate 102 and a plurality of LED dies 104 on the substrate 102 spaced apart from each other. For the sake of brevity, only three LED dies 104 are shown, but the present disclosure is not limited thereto. Each LED die 104 has a first electrode 112a (e.g., a positive electrode) and a second electrode 112b (e.g., a negative electrode). In some embodiments, the first electrode 112a is a negative electrode, and the second electrode 112b is a positive electrode. The first electrode 112a and the second electrode 112b are disposed on the same side of the LED die 104 facing away from the substrate 102 (may also referred to as the front side of the LED die 104). In some embodiments, the substrate 102 may be a sapphire substrate, a silicon substrate, a silicon carbide substrate, or a ceramic substrate. The LED dies 104 may be LED chips that emit blue, red, or green light.

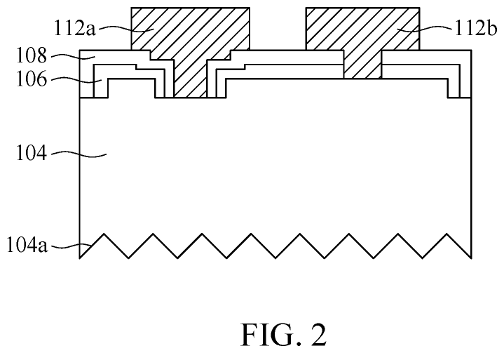

FIG. 2 illustrates a detailed cross-sectional structure of the LED die 104 shown in FIG. 1. In FIG. 2, a first reflection layer 106 is disposed on the LED die 104 and a second reflection layer 108 is further disposed on the first reflection layer 106. The first reflection layer 106 can reflect a waveband of light emitted from the LED die 104 to increase the EQE. The second reflection layer 108 can reflect the laser used in the selective LLO technique in the transfer process of the LED dies 104, to prevent the laser-induced thermal damage to the LED dies. In some embodiments, the first electrode 112a and the second electrode 112b penetrate the second reflection layer 108 and electrically connect to the LED die 104, as shown in FIG. 2. The process of forming the first reflection layer 106 and the second reflection layer 108 is described in more detail below.

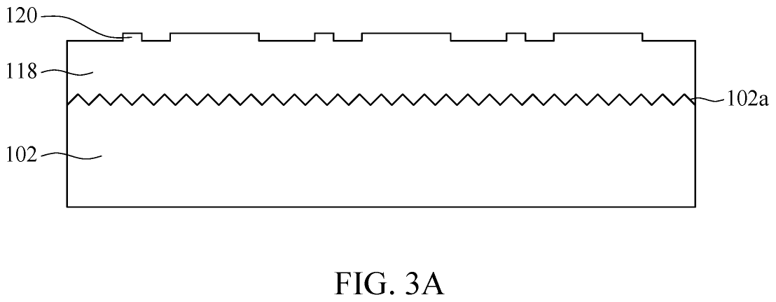

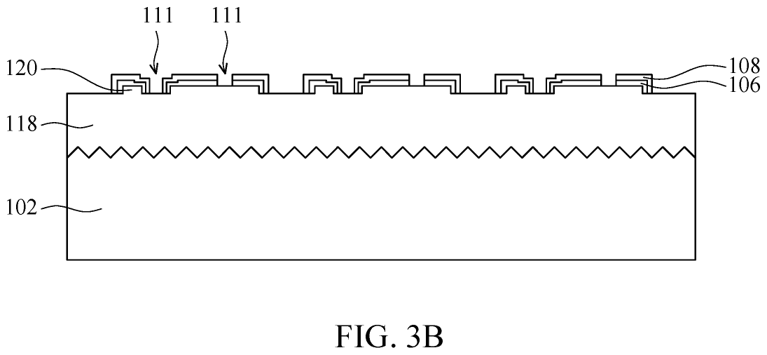

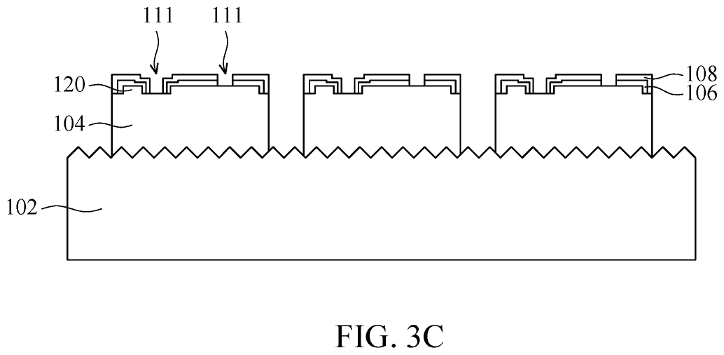

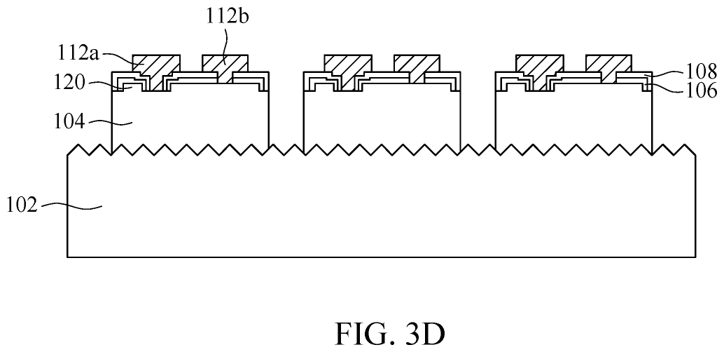

FIGS. 3A-3D illustrate cross-sectional views of various intermediate stages of forming process of an LED die 104 in accordance with some embodiments of the present disclosure. Referring to FIG. 3A, an epitaxial semiconductor layer 118 is formed on the semiconductor substrate 102. In some embodiments, before forming the epitaxial semiconductor layer 118, a roughening process may be performed on the semiconductor substrate 102 to form a periodically roughened surface 102a. In some embodiments, a patterned sapphire substrate (PSS) technique is used to form a patterned substrate to increase light extraction efficiency. For example, a patterned substrate may be formed by photolithography and etching processes. During a photolithography process, a photoresist layer (not shown) is first applied to the semiconductor substrate 102 by, for example, spin coating. Then, the photoresist layer is exposed according to a patterned mask and is developed to form the periodic patterns in the photoresist layer. The photoresist layer with the periodic patterns can be used as an etch mask to pattern the semiconductor substrate 102. The patterned photoresist layer is then used to protect portions of the surfaces of the semiconductor substrate 102 while a plurality of cavities is formed by an etching process that etches into the surface of the semiconductor substrate 102 in unprotected regions, thereby leaving the periodic roughened surface 102a. Then, the photoresist layer is removed by, for example, ashing. In some examples, the periodic roughened surface 102a is formed by a dry etch process, such as reactive ion etching (RIE), a wet etch, or a combination thereof.

It should be noted that the roughening process described herein is optional, and it may not be performed, or the roughening process may be performed on the LED die 104 in a subsequent process (details are provided below). In some embodiments, the epitaxial semiconductor layer 118 includes a first type semiconductor layer, a light-emitting layer, and a second type semiconductor layer sequentially formed on the substrate 102. For example, the first type semiconductor layer and the second type semiconductor layer may be different types of semiconductor materials. For example, the first type semiconductor layer is gallium nitride with n-type conductivity (n-GaN) and the second type semiconductor layer is gallium nitride with p-type conductivity (p-GaN), and vice versa. Other III-V compounds may be used, such as: indium nitride (InN), aluminum nitride (AlN), indium gallium nitride (InₓGa₍₁₋ₓ₎N), aluminum gallium nitride (AlₓGa₍₁₋ₓ₎N), or aluminum indium gallium nitride (AlₓIn_{y}Ga_{(1-x-y)}N), wherein 0<x≤1, 0<y≤1, and 0≤x+y≤1. The light-emitting layer 119 may have a multiple quantum well (MQW) structure composed of semiconductor materials. The light-emitting layer may include other suitable light-emitting materials, and is not limited thereto. In one embodiment, the method for forming the epitaxial semiconductor layer 118 may include an epitaxial growth process, such as chemical vapor deposition (CVD), metal organic chemical vapor deposition (MOCVD), molecular beam epitaxy (MBE), hydride vapor phase epitaxy (HYPE), liquid phase epitaxy (LPE) or other suitable CVD methods.

Still referring to FIG. 3A, then, a patterned mesa structure 120 is formed on the epitaxial semiconductor layer 118 by a patterning process to define the regions for the to-be formed features. The patterning process described above may include photolithography and etching processes, which are similar to the patterning process described above, and are not repeated herein for brevity.

Referring to FIG. 3B, a first reflection layer 106 is formed on the mesa structure 120. The first reflection layer 106 has a high reflectivity for a waveband of the light emitted from the LED die 104, for example, greater than 90%, to reflect the waveband of the light emitted from the LED die 104 so as to increase the EQE. In some embodiments, the first reflection layer 106 may be a distributed Bragg reflector (DBR). In one embodiment, the DBR layer may include a periodic structure formed by alternating combination of two material layers with different refractive index, or a dielectric waveguide with a periodic variation in the effective refractive index. In one embodiment, the material of the DBR layer may include an insulator. For example, the material of the DBR layer may include silicon oxide (SiO₂), titanium oxide (TiO₂), tantalum oxide (Ta₂O₅), aluminum oxide (Al₂O₃) or silicon nitride (Si₃N₄). The thickness of the each DBR layer is related to the wavelength of the incident light. When the product of the refractive index and the optical thickness of the each DBR layer is equal to a quarter of the wavelength of the incident light, the optical path difference between the incident light and the reflected light is equal to an integral multiple of the incident light wavelength (nλ, n=1,2,3 . . . ), and result in constructive interference. The light may not penetrate the DBR layer. Due to the above principles and material properties, the DBR layer may reflect the waveband of light emitted from the LED die 104, and hence increase the EQE. In one embodiment, the higher the number of the DBR layers, the more significant the light reflection. In some embodiments, the thickness of the first reflection layer 106 may be controlled in the range of 0.1 μm-4 μm, for example, 0.6 μm-2 μm.

Then, a second reflection layer 108 is formed on the first reflection layer 106. The second reflection layer 108 has a high reflectivity, e.g., greater than 90%, for the laser of the selective LLO technique used in the process of transferring the LED dies 104; and therefore, the second reflection layer 108 may reflect the laser used in the subsequent selective LLO technique, to prevent the laser-induced thermal damage to the LED dies. In some embodiments, the second reflection layer 108 may be a DBR layer with different thickness to that of the first reflection layer 106. In some embodiments, the material of the DBR layer of the second reflection layer 108 may be similar to that of the first reflection layer 106. In some embodiments, the material of the DBR layer of the second reflection layer 108 may be the same to that of the first reflection layer 106 to reduce the difficulties of the manufacturing process. In some embodiments, depending on the design requirements of the light-emitting device, the material of the DBR layer of the second reflection layer 108 may be different from that of the first reflection layer 106. In some embodiments, the higher the number of layers in the second reflection layer 108, the more significant the light reflection. In some embodiments, the thickness of the second reflection layer 108 can be controlled in the range of 0.1 μm-4 μm, for example, 0.6 μm-2 μm. In some embodiments, the thickness of the second reflection layer 108 is less than the thickness of the first reflection layer 106.

Then, the first reflection layer 106 and the second reflection layer 108 are patterned to form recesses 111 extending through the first reflection layer 106 and the second reflection layer 108 to expose a portion of the epitaxial semiconductor layer 118, as shown in FIG. 3B. The recesses 111 can be used to form the electrodes of the LED chips in the subsequent process. The patterning process may be similar to the patterning process described above, and are not repeated herein for brevity.

Referring to FIG. 3C, the epitaxial semiconductor layer 118 is etched to form LED dies 104 spaced apart from each other. The etching process may include dry etching such as reactive ion etching (RIE), wet etching, or a combination thereof.

Referring to FIG. 3D, a first electrode 112a and a second electrode 112b penetrating through the first reflection layer 106 and the second reflection layer 108 are formed, wherein the first electrode 112a and the second electrode 112b are in physical contact with the LED die 104. In some embodiments, the material of the first electrode 112a and the second electrode 112b may be made of metal or a metal alloy. For example, the metal materials of the first electrode 112a and the second electrode 112b may include copper (Cu), aluminum (Al), indium (In), tin (Sn), gold (Au), platinum (Pt), zinc (Zn), silver (Ag), titanium (Ti), nickel (Ni) or a combination thereof. In some embodiments, the first electrode 112a and the second electrode 112b may be formed by CVD like low pressure chemical vapor deposition (LPCVD) and plasma chemical vapor deposition (PECVD), physical vapor deposition (PVD), atomic layer deposition (ALD) or other suitable deposition processes. Subsequently, the electrode layer may be patterned by photolithography and etching processes, as shown in FIG. 3D. For example, the patterning process may be similar to the patterning process described above, and are not repeated herein for brevity.

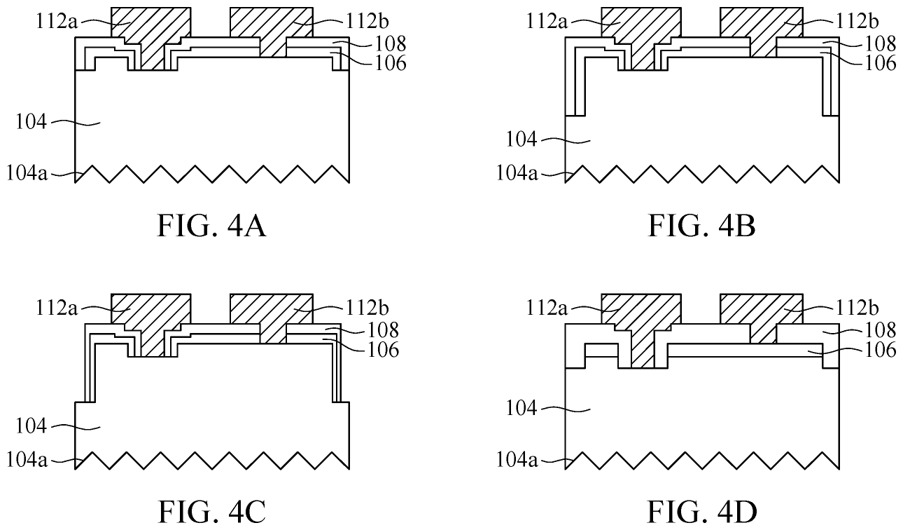

FIGS. 4A-4D illustrate cross-sectional views of forming an LED die having different types and/or different profiles of reflection layers in accordance with various embodiments of the present disclosure. Referring to FIG. 4A, in some embodiments, both the first reflection layer 106 and the second reflection layer 108 are DBR layers, and the first reflection layer 106 may reflect the light emitted from the LED die 104 to the front side of the LED die 104 to increase the EQE. The second reflection layer 108 may reflect the laser of the subsequent selective LLO technique in the process of transferring the LED dies 104 so as to prevent laser-induced thermal damage to the LED dies. Moreover, the first reflection layer 106 and the second reflection layer 108 may extend towards the substrate to cover most of the sidewalls of the LED dies 104, so the extended portions of the first reflection layer 106 may reflect the light emitted to the left side and the right side of the LED die 104 from the LED die 104 to increase the EQE. The extended portions of the second reflection layer 108 may reflect the laser of the selective LLO technique in the process of transferring the LED dies 104, as shown in FIGS. 4B and 4C. In some embodiments, the sidewalls of the second reflection layer 108 are aligned with the exposed sidewalls of the LED die 104; and the thicker first reflection layer 106 and the thicker second reflection layer 108 may be helpful to increase the EQE. And the reflection of the laser of the subsequent selective LLO technique in the process of transfer may be enhanced. Alternatively, in some embodiments, the sidewalls of the second reflection layer 108 may be retracted from the exposed sidewalls of the LED die 104, as shown in FIG. 4C, which may reduce the complexity of the process and omit the need for additional steps to align the sidewalls of the second reflection layer 108 with the exposed sidewalls of the LED die 104.

Alternatively, in another embodiment, the first reflection layer 106 may be a metal layer that can reflect the waveband of light emitted from the LED die 104 to increase the EQE, as shown in FIG. 4D. In some embodiments, the material of the first reflection layer 106 includes metals such as silver (Ag), aluminum (Al), and gold (Au). In some embodiments, the first reflection layer 106 may have a thickness of about 1000 Å to about 10000 Å. The first reflection layer 106 may be formed by CVD like LPCVD and PECVD, PVD, ALD, or other suitable deposition processes. In an embodiment, when the first reflection layer 106 is a metal layer, after the epitaxial semiconductor layer 118 is formed, the metal layer may be formed directly. Then, the metal layer and the epitaxial semiconductor layer 118 may be etched to form a mesa structure 120 and a patterned first reflection layer 106 on the mesa structure 120. Next, a patterned second reflection layer 108 is formed on the first reflection layer 106, and the patterning process may be similar to the patterning process described above. The patterned second reflection layer 108 exposes a portion of the first reflection layer 106 and a portion of the epitaxial semiconductor layer 118. Finally, the first electrode 112a is formed to contact the epitaxial semiconductor layer 118, and the second electrode 112b is formed to contact the first reflection layer 106, as shown in FIG. 4D. For the sake of brevity, the cross-sectional views of the process of the embodiment merely illustrates one configuration of the LED die 104 and the first reflection layer 106, but the configuration may also be any of one shown in FIGS. 4A-4D.

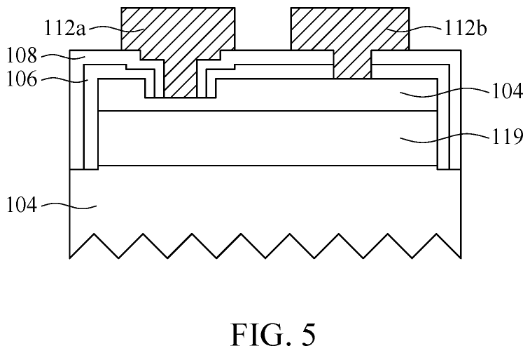

Referring to FIG. 5, the first reflection layer 106 laterally covers the light-emitting layer 119 in accordance with some embodiments of the present disclosure. A bottommost end of the extend portions (sidewalls) of the first reflection layer 106 may be lower than or equal to a bottom surface of the light-emitting layer 119 to reflect the light emitted to the left side and the right side of the light-emitting layer 119 from the light-emitting layer 119 to increase the EQE of the LED die 104.

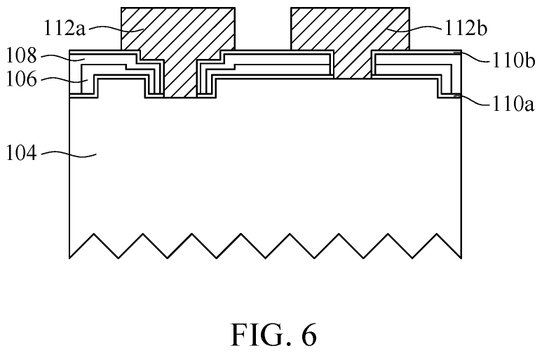

Referring to FIG. 6, before forming the first reflection layer and/or after forming the second reflection layer, a barrier film 110a and/or 110b may be formed on the LED die 104 and/or on the second reflection layer 108, depending on the design requirements in accordance with other embodiments of the present disclosure. The barrier films 110a and 110b cover the surfaces of the first reflection layer 106 and the second reflection layer 108, which not only protects the first reflection layer 106 and the second reflection layer 108 from damage caused by external substances such as moisture or oxygen, but also fills the defects caused by the deposition of the reflection layer to prevent leakage current so the reliability of the LED die 104 can be improved. In some embodiments, each of the barrier films 110a, 110b may include inorganic materials, such as dielectric materials (e.g., SiO₂, Al₂O₃ or Si₃N₄). In some embodiments, the barrier films 110a and 110b may be multi-layer barrier films disposed on the surface of the first reflection layer 106 and/or the second reflection layer 108 by coating or lamination. In some embodiments, the thickness of the barrier films 110a, 110b is separately greater than 10 nm and less than 500 nm.

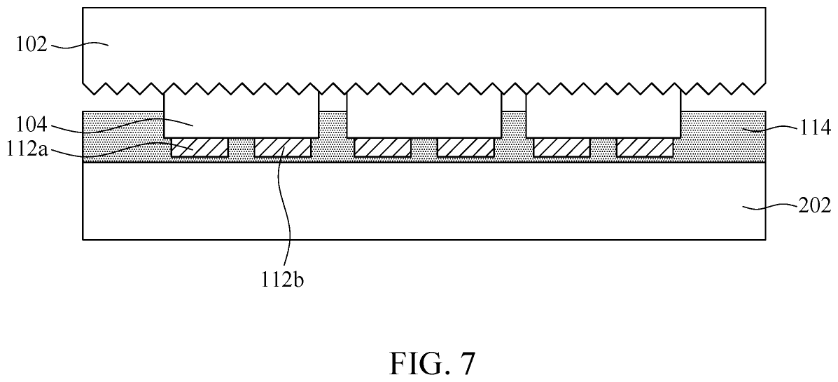

FIGS. 7, 8, 9, 10, 11, 12, 13, 14, 15, and 16 illustrate cross-sectional views of various intermediate stages of mass transfer process of LED dies in accordance with some embodiments of the present disclosure.

Referring to FIG. 7, first, a carrier 202 with a first adhesion layer 114 (also referred to as a glue) is provided. In some embodiments, the material of the carrier 202 may include a plastic substrate, a glass substrate, a silicon substrate or a sapphire substrate, or a substrate made of another suitable material for the carrier 202. In some embodiments, the first adhesion layer 114 may be UV glue which can be reacting with the laser used later. In some embodiments, the first adhesion layer 114 decomposes after absorbing the applied laser, such that the LED dies 104 are peeled off from the first adhesion layer 114. In some embodiments, the waveband of the laser used is less than 420 nm. For example, the wavelength of the waveband may be 248, 260, 280, or 355 nm.

In some embodiments, the first adhesion layer 114 may be formed on the carrier 202 by spin coating. Next, the first electrode 112a and the second electrode 112b of the semiconductor device 10 shown in FIG. 1 are bonded to the first adhesion layer 114 on the carrier 202. In some embodiments, the first adhesion layer 114 fills into the gaps between the LED dies 104, attaches to parts of the sidewalls of the LED dies 104, and covers the first electrode 112a and the second electrode 112b, but are not in direct contact with the substrate 102, as shown in FIG. 7. In some embodiments, the first adhesion layer 114 covers 100% of the top surface and 80% of the side surface of the LED dies 104. In other embodiments, the first adhesion layer 114 attaches to the overall top surface and side surface of the LED dies 104, and directly contacts the substrate 102 (not shown).

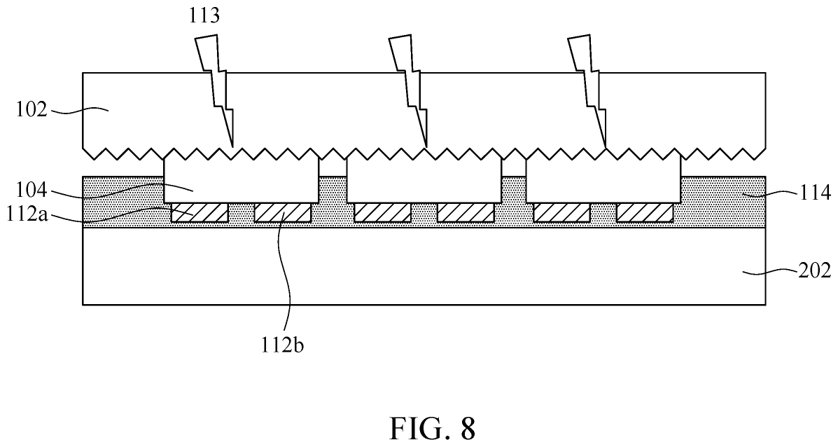

Referring to FIG. 8, the substrate 102 is removed by an LLO process 113 and the LED dies 104 are transferred to the carrier 202. In some embodiments, an LLO process 113 is applied to the substrate 102 side to remove the substrate 102. In some embodiments, the wavelength of the laser used in the LLO process 113 is below 420 nm, for example, the wavelength is 248, 260, 280, or 355 nm. In some embodiments, the material of the LED dies 104 may absorb all the laser energy used in the laser LLO process to avoid the LED dies 104 from being damaged by the laser. In an embodiment, the LED dies 104 includes a III-V compound (e.g., gallium nitride), the III-V compound may absorb all the laser energy at the interface with the substrate 202 to prevent LED die 104 from being damaged by laser and to improve the yield of the light-emitting device.

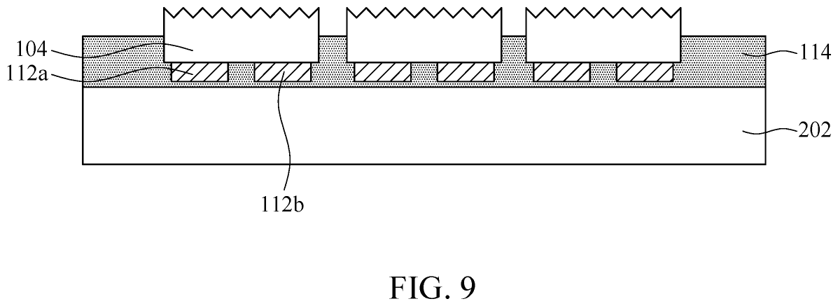

Referring to FIG. 9, in some embodiments, since the substrate 102 has a patterned periodic surface 102a, the LED die 104 also has a periodic roughened surface 104a at the interface with the substrate 102. After the LLO process, the periodically roughened surface 104a of the LED die 104 may be exposed to increase the light extraction efficiency of the LED die 104.

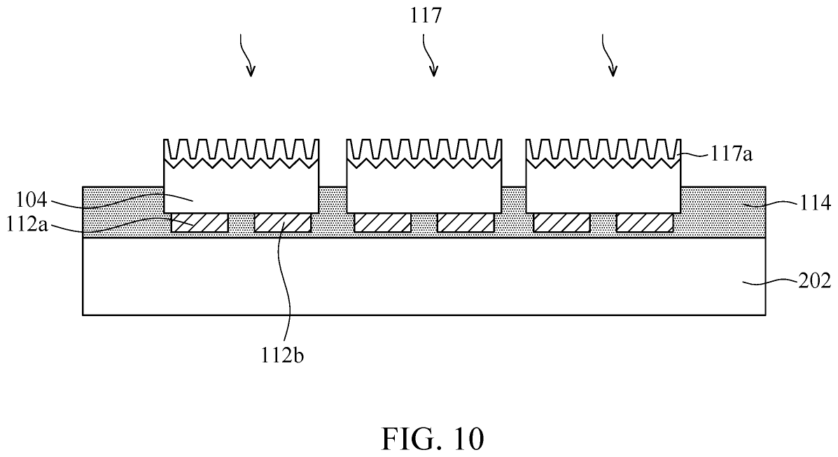

Referring to FIG. 10, in other embodiments, after the substrate 102 is removed, a roughening process 117 may be performed to form a roughened surface 117a on the exposed surface of the LED die 104, depending on the design requirements, to increase the light extraction efficiency of the LED die 104. In some embodiments, the roughened surface 117a may include a semiconductor material and/or a polymer. For example, a light transmitting layer (not shown) may be optionally formed on the periodically roughened surface of the LED die 104. The light transmitting layer may include polymers such as silicone or resin, and may be formed by molding, glue-filling, or other suitable process. Next, a roughening process 117 is performed on the light transmitting layer to form a periodic roughening surface 117a by, for example, abrasive blasting or surface etching. In some embodiments, the surface roughness of the roughened surface 117a may be in the range of 0.1 μm-3 μm, for example, 0.2 μm-2 μm, but is not limited thereto.

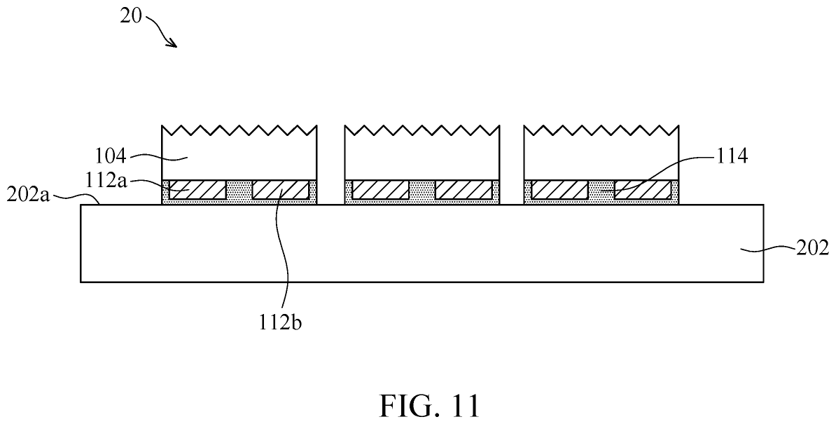

Referring to FIG. 11, a light-emitting device 20 is formed. Continuing with the structure shown in FIG. 9, the first adhesion layer 114 between the sidewalls of the LED dies 104 is etched to expose the upper surface 202a of the carrier 202 and the LED dies 104 are separated in favor of subsequent selective transfer of the LED dies 104. Hence, the difficulties of selective transferring caused by the first adhesion layer 114 remaining between each LED die 104 are reduced. The etching process may include dry etching such as reactive ion etching (RIE), wet etching, or a combination thereof.

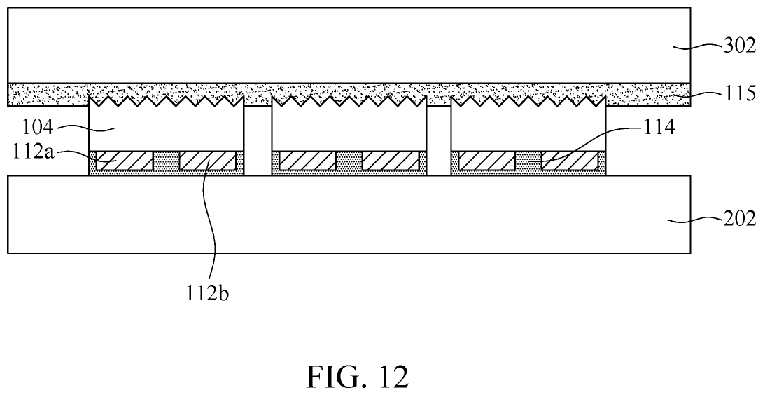

Referring to FIG. 12, which continues with the structure shown in FIG. 11, a second carrier 302 with a second adhesion layer 115 thereon is provided. In some embodiments, the material of the second carrier 302 may include a plastic substrate, a glass substrate, a silicon substrate or a sapphire substrate, or a substrate made of another suitable material for the second carrier 302. In some embodiments, the second adhesion layer 115 may be an elastic polymer material with viscosity. In some embodiments, the elastic polymer material with viscosity may include a siloxane polymer based material, such as polydimethylsiloxane (PDMS). In some embodiments, the second adhesion layer 115 may be formed by spin coating. Then, bonding the back side of the light-emitting device 20 (the side facing away from the electrodes) shown in FIG. 11 to the second adhesion layer 115 on the second carrier 302, as shown in FIG. 12.

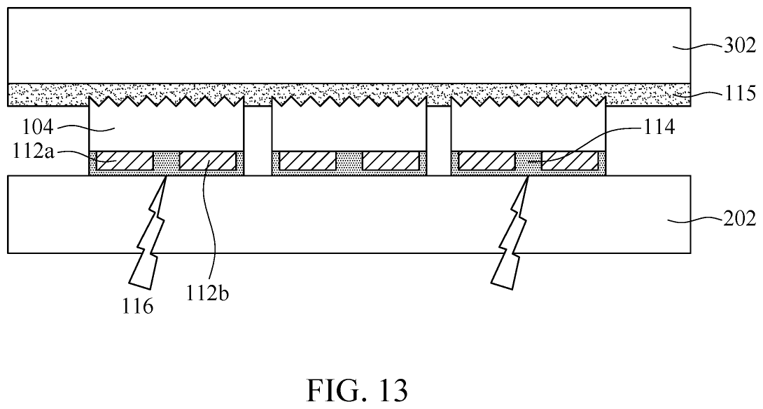

Referring to FIG. 13, which follows the structure shown in FIG. 12, the LED dies 104 are selectively transferred to the second carrier 302. A plurality of the LED dies 104 is selectively peeled from the first carrier 202 by a selective LLO process 116 performed on the electrode side of each of the LED dies 104 that need to be transferred. In some embodiments, the waveband of the laser used in the selective LLO process 116 is below 420 nm, for example, the wavelength of the waveband is 248, 260, 280, or 355 nm. In some embodiments, the first adhesion layer 114 may not absorb the laser used in the selective LLO process 116 completely, and the second reflection layer 108 on the LED dies 104 may reflect the laser used in the selective LLO process 116, thereby reducing the influence of the high temperature from the laser to the LED dies 104 so the yield of transfer is increased.

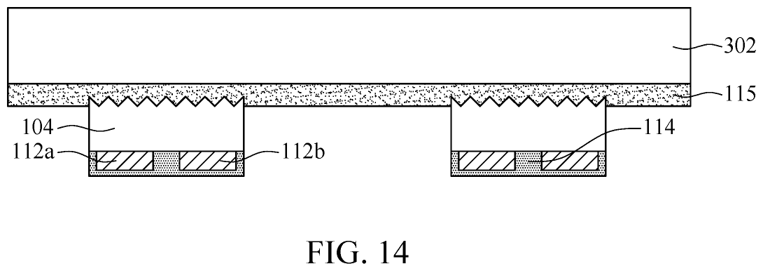

Referring to FIG. 14, which follows the structure shown in FIG. 13, the first carrier 202 is removed so that the LED dies 104 needed to be transferred leave the first carrier 202 and adhere to the second adhesion layer 115, while the LED dies 104 that do not need to be transferred remain on the first carrier 202 and leave the second adhesion layer 115.

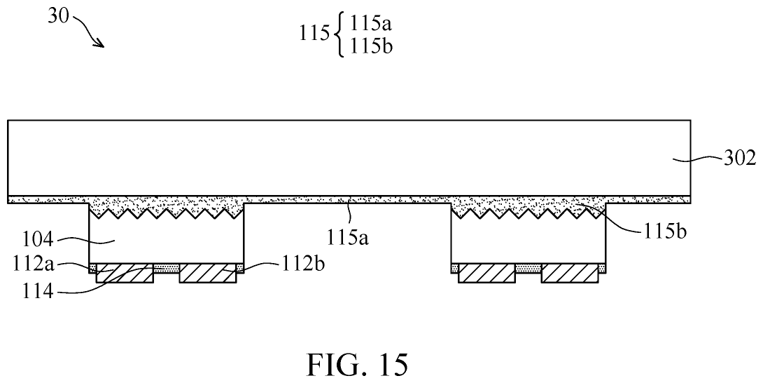

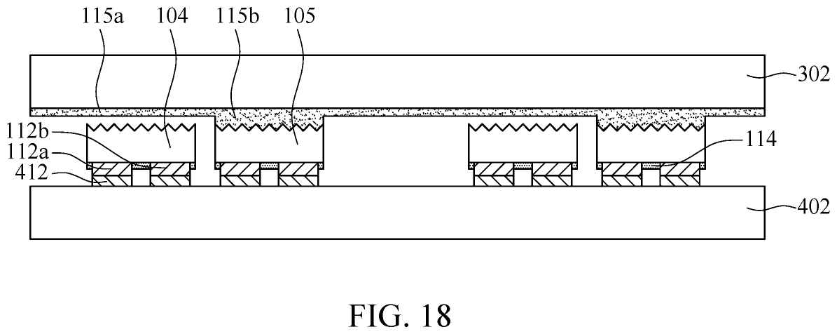

Referring to FIG. 15, a light-emitting device 30 is formed. Following the structure shown in FIG. 14, the first adhesion layer 114 on the LED die 104 is etched to expose bottom surfaces and portions of the sidewalls of the first electrode 112a and the second electrode 112b of the LED die 104, to facilitate the subsequent bonding process such that the LED die 104 may be electrically connect to the target back plate. In some embodiments, the etching process may be similar to the etching process used in etching the first adhesion layer. In some embodiments, the etching process may include other suitable processes. In some embodiments, the first adhesion layer 114 remains on the front side of the LED die 104 and covers portions of the sidewalls of the first electrode 112a and the second electrode 112b, to protect the LED die 104, and the first electrode 112a and the second electrode 112b. In some embodiments, while etching the first adhesion layer 114 of the LED dies 104, a portion of the second adhesion layer 115 between the LED dies 104 may also be etched so that second adhesion layer 115 between the dies 104 is thinner The thinner portion may prevent the LED dies from accidentally adhering to the existing LED dies originally on the back plate while transferring the LED dies to the back plate (as is described in detail below in conjunction with FIG. 18). In some embodiments, the second adhesion layer 115 includes a first portion 115a between the LED dies 104 and a second portion 115b in direct contact with the LED dies 104. It should be noted that the etching process etches the first portion 115a between the LED dies 104 which are served as a hard mask to keep the second portion 115b in direct contact with the LED dies 104 intact. Therefore, the thickness of the first portion 115a between the LED dies 104 is thinner than the thickness of the second portion 115b directly contacting the LED dies 104. In some embodiments, the second adhesion layer 115 has an irregular surface. In some embodiments, the thickness of the second adhesion layer 115a between the LED dies 104 is different from the thickness of the second adhesion layer 115b in direct contact with the LED dies 104.

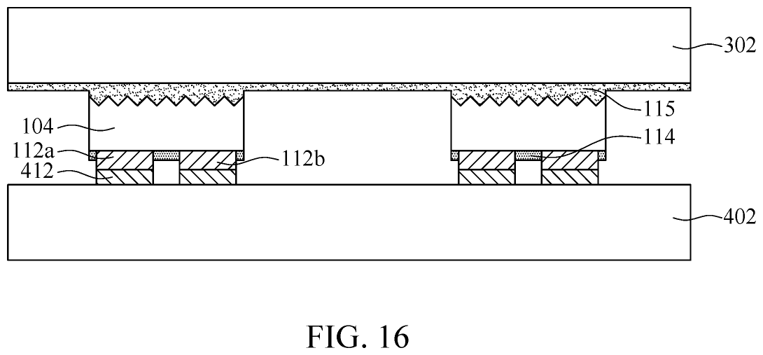

Referring to FIG. 16, which follows the structure shown in FIG. 15, a back plate 402 with a plurality of conductive members 412 thereon is provided. In some embodiments, the material of the back plate 402 may include (but is not limited to) a glass substrate, a plastic substrate, or a substrate made of another suitable material for the back plate 402. The conductive members 412 may be a metal electrode. For example, the material of the conductive members 412 may include (but is not limited to) nickel (Ni), tin (Sn), indium (In), gold (Au), titanium (Ti), copper (Cu) or combination thereof. In some embodiments, the conductive member 412 may be pre-melted to have adhesive properties, or the conductive member 412 may further include solder or an adhesive material with similar adhesive function. Next, the first electrode 112a and the second electrode 112b of the light-emitting device 30 shown in FIG. 15 are bonded to the conductive members 412 on the back plate 402. In some embodiments, the first electrode 112a and the second electrode 112b are respectively in electrical contact with the conductive members 412 as shown in FIG. 16.

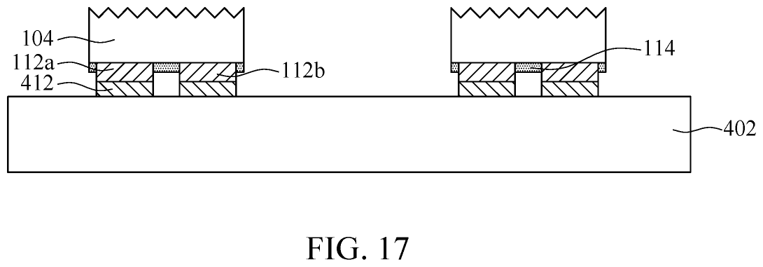

Referring to FIG. 17, which follows the structure shown in FIG. 16, the second carrier 302 is removed, so that the LED dies 104 that need to be transferred leave the second carrier 302 and are bonded to the conductive members 412 on the back plate 402 as shown in FIG. 17.

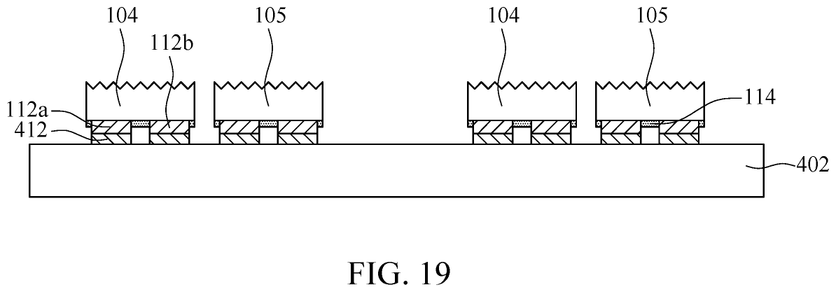

The transfer process of the present disclosure can selectively transfer the LED dies 104 to the target back plate 402, depending on the design requirements of the target back plate 402. For example, the first type LED dies 104 (such as blue LEDs) that are spaced apart from each other may be transferred to the target back plate 402 first, and then the second type LED dies 105 (such as red LEDs) may be transferred to the space between the first type LED dies 104 on the target back plate 402, as shown in FIGS. 18 and 19. The above description is merely an example, and is not intended to limit the present disclosure, and more types of the LED dies may be transferred to the target back plate 402 according to the design requirements of the back plate. In addition, since the thickness of the first portion 115a between the light-emitting diode die 104 is thinner than that of the second portion 115b in direct contact with the LED die 104 as shown in FIG. 18, it can prevent the second adhesion layer 115a from adhering to the LED dies 104 that has been transferred to the target back plate in the subsequent process to increase the yield of the process. Then, the second carrier 302 is removed. In some embodiments, the spacing between each LED die 104 can be changed depending on the design requirements of the back plate. The transfer process of the present disclosure can not only apply to different types of LED dies 104, but also be widely used in the field of various micro semiconductor structures.

It should be noted that the present disclosure generally describes a process for transferring multiple LED dies in the same time. Additional processes can be provided, and the processes may be performed in another logical order. For example, fewer or additional carriers may be provided; a different order of steps may be performed; additional carriers may be formed and removed, and/or similar processes may be performed. Furthermore, different structures and steps can be performed to form the LED dies.

The light-emitting device provided by the embodiments of the present disclosure includes a first reflection layer and a second reflection layer. The first reflection layer is on the LED die and the second reflection layer is on the first reflection layer. By disposing the first reflection layer on the LED die, the first reflection layer can reflect the light emitted from the LED die to improve the EQE of the LED die, therefore, the light extraction efficiency of the light-emitting device is also improved. In addition, by disposing the second reflection layer on first reflection layer on the LED die, the second reflection layer can reflect the laser used in the selective LLO process, so the influence of the high temperature from the laser to the LED dies is reduced, and therefore increase the yield of the transfer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting device, comprising:
a substrate;
a plurality of light-emitting diode (LED) dies on the substrate;
a first reflection layer on the LED dies to reflect a waveband of light emitted from the LED dies; and
a second reflection layer on the first reflection layer to reflect a laser waveband, wherein a wavelength of the laser waveband is less than 420 nm.

2. The light-emitting device of claim 1, wherein the second reflection layer is a distributed Bragg reflector (DBR) layer.

3. The light-emitting device of claim 1, wherein the first reflection layer is a metal reflection layer, a distributed Bragg reflector (DBR) layer, or a combination thereof.

4. The light-emitting device of claim 1, wherein the second reflection layer covers an upper surface and parts of sidewalls of the LED dies.

5. The light-emitting device of claim 4 wherein the second reflection layer is aligned with exposed sidewalls of the LED dies.

6. The light-emitting device of claim 4 wherein the second reflection layer is indented from exposed sidewalls of the LED dies.

7. The light-emitting device of claim 1, further comprising:
a barrier film on the second reflection layer above and/or below the first reflection layer.

8. The light-emitting device of claim 1 wherein each of the LED dies comprises:
a light-emitting unit, wherein the first reflection layer and the second reflection layer are disposed on the light-emitting unit; and
a pair of electrodes penetrating the second reflection layer and connected to the light-emitting unit.

9. A light-emitting device, comprising:
a carrier;
a plurality of light-emitting diode (LED) dies on the substrate and spaced apart from each other, wherein each of the LED dies comprises a pair of electrodes facing toward the carrier; and
a plurality of glues between the carrier and the LED dies and wrapping the electrodes, wherein upper surfaces of the carrier are exposed between the LED dies.

10. The light-emitting device of claim 9, further comprising:
a first reflection layer between a light-emitting unit and the electrodes of each of the LED dies to reflect a waveband of light emitted from the LED dies.

11. The light-emitting device of claim 10, wherein the first reflection layer laterally covers the light-emitting unit.

12. The light-emitting device of claim 10, wherein the first reflection layer covers upper surfaces and at least parts of sidewalls of the LED dies.

13. The light-emitting device of claim 10, wherein the first reflection layer is a distributed Bragg reflector (DBR) layer.

14. The light-emitting device of claim 10, further comprising:
a second reflection layer between the first reflection layer and the electrodes, wherein the second reflection layer is configured to reflect a laser waveband, wherein a wavelength of the laser waveband is less than 420 nm.

15. The light-emitting device of claim 14, wherein the second reflection layer is a distributed Bragg reflector (DBR) layer.

16. A light-emitting device, comprising:
a carrier;
a light-emitting diode (LED) die on the substrate, wherein the LED die comprises a pair of electrodes facing away from the carrier;
an adhesion layer disposed between the carrier and the LED die; and
a glue over the LED die, wherein the electrodes are exposed from the glue.

17. The light-emitting device of claim 16, wherein the glue wraps around parts of sidewalls of the electrodes.

18. The light-emitting device of claim 16, wherein the adhesion layer comprises:
a first region physically contacting the LED die; and
a second region not physically contacting the LED die, wherein a thickness of the adhesion layer in the second region is smaller than a thickness of the adhesion layer in the first region.

19. The light-emitting device of claim 16, further comprising:
a first reflection layer on the LED die, wherein the first reflection layer is configured to reflect a waveband of light emitted from the LED die.

20. The light-emitting device of claim 19, wherein the first reflection layer covers upper surfaces and at least parts of sidewalls of the LED die.

21. The light-emitting device of claim 19, wherein the LED die further comprises a light-emitting unit, and the first reflection layer laterally covers the light-emitting unit.

22. The light-emitting device of claim 19, wherein the first reflection layer is a distributed Bragg reflector (DBR) layer.

23. The light-emitting device of claim 19, further comprising:
a second reflection layer on the first reflection layer to reflect a laser waveband, wherein a wavelength of the laser waveband is less than 420 nm.

24. The light-emitting device of claim 23, wherein the first reflection layer is a distributed Bragg reflector (DBR) layer.

25. A method, comprising:
providing a substrate, wherein the substrate has a plurality of light-emitting diode (LED) dies spaced apart from each other, wherein a front side of each of the LED dies has a pair of electrodes facing away from the substrate;
bonding a first carrier to the front side of the LED dies through a glue, with the electrodes facing toward the first carrier;
removing the substrate from a back side of the LED dies;
removing a part of the glue between the LED dies to expose upper surfaces of the first carrier between the LED dies;
bonding a second carrier to the back side of the LED dies through an adhesion layer;
removing the first carrier from the front side of at least one of the LED dies, such that the at least one of the LED dies adheres to the second carrier;
removing a part of the glue on the at least one of the LED dies on the second carrier to expose the electrodes;
bonding a back plate to the exposed electrodes on the at least one of the LED dies; and
removing the second carrier and the adhesion layer from a back side of the at least one of the LED dies.

26. The method of claim 25, wherein the removing the first carrier from the front side of at least one LED die comprises a selective laser lift off process.

27. The method of claim 26, wherein the LED dies further comprise a reflection layer on a side close to the electrodes to reflect a laser used in the laser lift off process.

28. The method of claim 25, wherein during the bonding the first carrier to the front side of the LED dies through a glue, the glue covers parts of sidewalls of the LED dies.

29. The method of claim 25, further comprising:
removing a part of the adhesion layer that is not adhered to the at least one of the LED dies.

30. The method of claim 25, after the removing the substrate from the back side of the LED dies, further comprising:
performing a roughening process on surfaces of the LED dies to form periodic roughened surfaces.

31. The method of claim 25, wherein the providing the substrate further comprises:
forming a semiconductor layer with a plurality of mesas on the substrate;
sequentially forming a first reflection layer and a second reflection layer on the mesas;
etching the semiconductor layer to form the LED dies spaced apart from each other; and
forming the electrodes on the second reflection layer, wherein the electrodes penetrate the first reflection layer and the second reflection layer.

32. The method of claim 31, before or after the forming the first reflection layer and the second reflection layer, further comprising:
forming a barrier film below the first reflection layer or above the second reflection layer.
